(19) United States
(12) Patent Application Publication
(10) Pub. No.: US 2011/0171390 A1
(43) Pub. Date: Jul. 14, 2011

(54) FIXTURE FOR COATING APPLICATION

(75) Inventors: Bartolomeo Palmieri, Guilford, CT (US); Harvey R. Toppen, Glastonbury, CT (US)

(73) Assignee: United Technologies Corporation One Financial Plaza, Hartford, CT (US)

(21) Appl. No.: 12/684,587

(22) Filed: Jan. 8, 2010

(51) Int. Cl. B05D 1/02; C23C 16/00

(52) U.S. Cl. 427/425; 118/723 R; 118/500

(57) ABSTRACT

A fixture assembly for use with air plasma spraying coating application processes includes a support member configured to be rotationally indexed, a first buttress, and a second buttress. The support member includes a first portion and a second portion fixedly supported by the first portion in a T-shaped configuration. The second portion has a first end and an opposite second end. The first buttress is secured to the second portion of the support member at or near the first end, with the first buttress configured to secure a first work piece. The second buttress is secured to the second portion of the support member at or near the second end, with the second buttress configured to secure a second work piece. The second buttress is arranged symmetrically with respect to the first buttress.

### BACKGROUND

The present invention relates to a fixture assembly for use with coating application processes.

Coatings are utilized in a variety of settings. For example, modern gas turbine engines can include thermal barrier coatings (TBCs), environmental coatings, etc. to help promote efficient and reliable operation. Application of coatings can involve a variety of different application methods, such as plasma spraying.

### SUMMARY

A fixture assembly for use with air plasma spraying coating application processes according to the present invention includes a support member configured to be rotationally indexed, a first buttress, and a second buttress. The support member includes a first portion and a second portion fixedly supported by the first portion in a T-shaped configuration. The second portion has a first end and an opposite second end. The first buttress is secured to the second portion of the support member at or near the first end, with the first buttress configured to secure a first work piece. The second buttress is secured to the second portion of the support member at or near the second end, with the second buttress configured to secure a second work piece. The second buttress is arranged symmetrically with respect to the first buttress.

### BRIEF DESCRIPTION OF THE DRAWINGS

FIG. 1 is a perspective view of a fixture assembly according to the present invention.

FIG. 2 is a flow chart of a coating application method according to the present invention.

### DETAILED DESCRIPTION

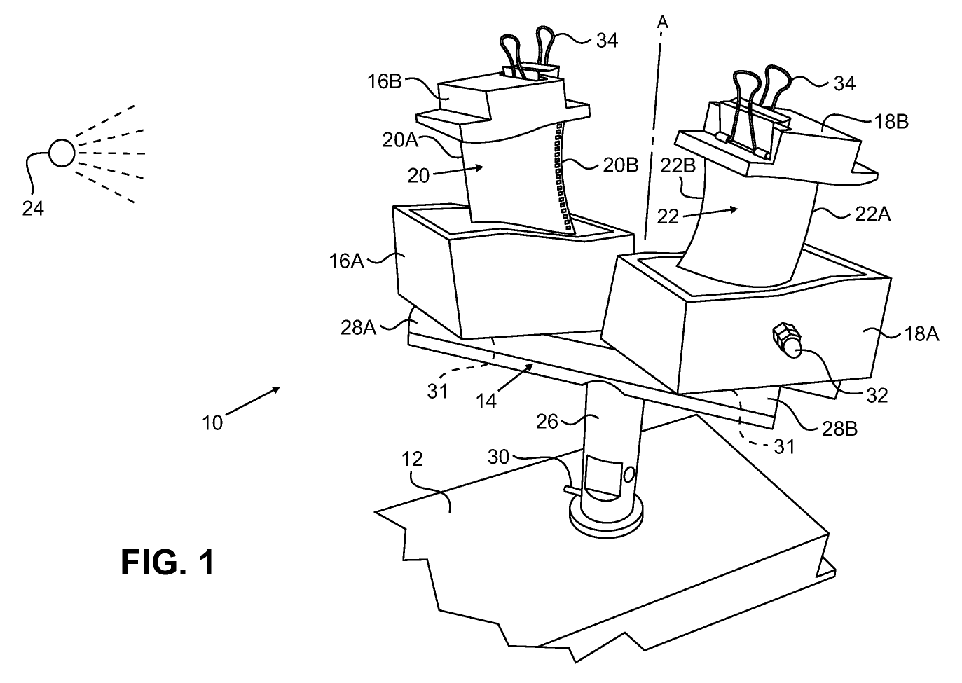

FIG. 1 is a perspective view of a fixture assembly 10 that includes a setup base 12, a support member 14, buttresses 16A, 16B, 18A and 18B, and first and second work pieces 20 and 22. The setup base 12 is used for assembling the support member 14, the buttresses 16A, 16B, 18A and 18B, and the first and second work pieces 20 and 22 of the fixture assembly 10. The support member 14 can be removed from the setup base 12 and engaged to a coating machine spindle (not shown) of a conventional configuration during use. A coating spray source 24 (shown schematically, for simplicity) is pointed at the fixture assembly 10 for delivering a coating, such as a thermal barrier coating (TBC), bond coating, environmental coating, etc. In one embodiment, the coating spray source 24 is an air plasma spray gun.

The support member 14 includes a first portion 26 and a second portion 28. The first portion extends substantially vertically (relative to the setup base 12 or a machine spindle), and can be rotationally indexed about a central axis A. In the illustrated embodiment, the first portion 26 is generally tubular in shape. A pin 30 extends outward from the first portion 26, generally perpendicular to the axis A, and can be used to facilitate rotationally indexing the support member 14 with a machine spindle engaged to which the support member 14 and the pin 30 are engaged. The second portion 28 of the support member 14 is fixedly supported by the first portion 26, and can be rotationally indexed together with the first portion 26. In the illustrated embodiment, the second portion 28 is an elongate beam with a generally U-shaped cross-section arranged with an open side of the U-shape facing in a generally downward direction. The second portion 28 includes a first end 28A and an opposite second end 28B. In the illustrated embodiment, the support member 14 is generally T-shaped with the second portion 28 arranged perpendicular to the first portion 26. It will be recognized that the particular shape and configuration of the first and second portions 26 and 28 of the support member 14 can vary as desired for particular applications. The support member 14 can be made of stainless steel, or other suitable materials.

The buttress 16A is secured at or near the first end 28A of the second portion 28 of the support member 14, and the buttress 18A is secured at or near the second end 28B of the second portion 28 of the support member 14. In the illustrated embodiment, the buttresses 16A and 18A are arranged symmetrically, such that the buttresses 16A and 18A are substantially parallel to one another and face in opposite directions (i.e., at approximately 180° relative to each other). The buttresses 16A and 18A can be secured to the second portion 28 of the support member 14 using suitable fasteners 31, such as bolts. Portions of the fasteners can be concealed within the second portion 28 of the support member 14 and within the buttresses 16A and 18A.

The work piece 20 is secured to the buttress 16A, and is thereby retained relative to the support member 14. The work piece 22 is secured to the buttress 18A, and is thereby also retained relative to the support member 14. Suitable fasteners 32 can be used to retain the work pieces 20 and 22 to the buttresses 16A and 18A. In the illustrated embodiment, the work pieces 20 and 22 are both gas turbine engine vanes with substantially identical geometries. In further embodiments, the work pieces can be other types of components desired to be coated such as blades, struts, etc. As shown in FIG. 1, the work piece 20 defines a leading edge 20A and an opposite trailing edge 20B. Likewise, the work piece 22 defines a leading edge 22A and an opposite trailing edge 22B. The work pieces 20 and 22 are secured to the buttresses 16A and 18A, respectively, such that the leading edges 20A and 22A face in opposite directions (i.e., at approximately 180° relative to each other).

The buttress 16B is secured to the work piece 20 opposite the buttress 16A, and the buttress 18B is secured to the work piece 22 opposite the buttress 18A. The buttresses 16B and 18B can be secured using clips 34 or other suitable fasteners. The buttresses 16A, 16B, 18A and 18B cover portions of the work pieces 20 and 22, and can help mask portions of the work pieces 20 and 22 during application of the coating.

Because the fixture assembly 10 secures both of the work pieces 20 and 22 to the support member 13, rotational indexing of the support member 14 relative to the coating spray source 24 repositions both of the work pieces 20 and 22 (as well as the buttresses 16A, 16B, 18A and 18B) simultaneously. Because the work pieces and the buttresses 16A, 16B, 18A and 18B are arranged symmetrically, indexing of the support member 14 provides for relatively even coating of the work pieces 20 and 22.

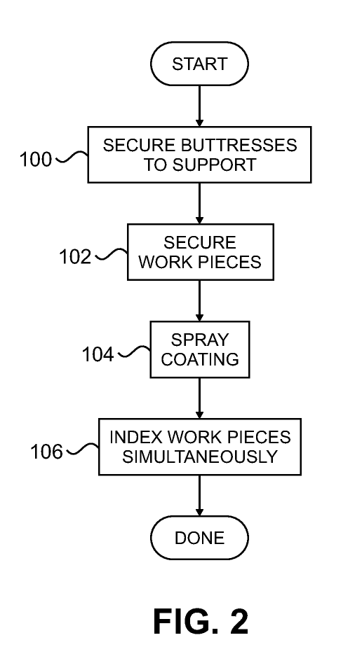

FIG. 2 is a flow chart of a coating application method. The method includes securing both of the buttresses 16A and 18A to the second portion 28 of the support member 14 (step 100). Further, the buttresses 16A and 18A, along with the buttresses 16B and 18B, are secured to the respective work pieces 20 and 22 (step 102). In various embodiments, the order of steps 100 and 102 can be reversed. The buttresses 16A and 18A position the work pieces 20 and 22 in a symmetrical arrangement relative to the support member 14. Once the work pieces 20 and 22 are secured, a spray of the coating is directed from the coating spray source 24 at both of the work pieces 20 and 22 (step 104). Next, the support member 14 is rotationally indexed about the axis A to symmetrically and simultaneously reposition the work pieces 20 and 22 relative to the spray of the coating from the coating spray source 24 (step 106). The coating process is continued until the coating is applied to the work pieces 20 and 22 as desired, at which point the work pieces 20 and 22 are removed from the buttresses 16A, 16B, 18A and 18B.

In view of the foregoing description, it will be recognized that the present invention provides numerous advantages and benefits. For example, the present invention allows for the simultaneous coating of two components, which provides for increased throughput of coating processes for an existing coating machine. Moreover, the present invention can produce relatively high quality coatings, while the fixture assembly of the present invention can be provided at a relatively low cost.

While the invention has been described with reference to an exemplary embodiment(s), it will be understood by those skilled in the art that various changes may be made and equivalents may be substituted for elements thereof without departing from the scope of the invention. In addition, many modifications may be made to adapt a particular situation or material to the teachings of the invention without departing from the essential scope thereof. Therefore, it is intended that the invention not be limited to the particular embodiment(s) disclosed, but that the invention will include all embodiments falling within the scope of the appended claims.

1. A fixture assembly for use with air plasma spraying coating application processes, the fixture assembly comprising:
a support member configured to be rotationally indexed, the support member comprising:
a first portion; and
a second portion fixedly supported by the first portion, the second portion having a first end and an opposite second end, wherein the first portion and the second portion define a T-shaped configuration;
a first buttress secured to the second portion of the support member at or near the first end, the first buttress configured to secure a first work piece; and
a second buttress secured to the second portion of the support member at or near the second end, the second buttress configured to secure a second work piece, wherein the second buttress is arranged symmetrically with respect to the first buttress.

2. The fixture assembly of claim 1, wherein first and second buttresses are configured to secure the first and second work pieces, respectively, having substantially identical geometries.

3. The fixture assembly of claim 1, wherein the support member comprises stainless steel.

4. The fixture assembly of claim 1, wherein the first buttress is secured to the second portion of the support member with a bolted connection.

5. The fixture assembly of claim 1, the support member further comprising:
a pin extending from the first portion.

6. The fixture assembly of claim 5, wherein the pin is spaced from the second portion.

7. The fixture assembly of claim 1, wherein the first and second buttresses are arranged at approximately 180° relative to each other.

8. A method for applying a coating, the method comprising:
securing first and second buttresses to a common support member;
securing the first and second buttresses to respective first and second work pieces, wherein the first and second buttresses position the first and second work pieces in a symmetrical arrangement;
directing a spray of the coating at both the first and second work pieces; and
rotationally indexing the support member to symmetrically and simultaneously reposition the first and second work pieces relative to the spray of the coating.
